(19) United States
(12) Patent Application Publication
(10) Pub. No.: US 2026/0237611 A1
(43) Pub. Date: Aug. 13, 2026

(54) ISOLATION VALVE GASKET

(71) Applicant: Lam Research Corporation, Fremont, CA (US)

(72) Inventors: Daniel Richard Cone, Oregon City, OR (US); Aaron Blake Miller, West Linn, OR (US); Shriram Vasant Bapat, Beaverton, OR (US); Nick Ray Linebarger, JR., Beaverton, OR (US)

(21) Appl. No.: 19/471,364

(22) PCT Filed: Apr. 3, 2024
(86) PCT No.: PCT/US2024/022885

§ 371 Date: Sep. 30, 2025

Related U.S. Application Data
(60) Provisional application No. 63/460,519, filed on Apr. 19, 2023.

(51) Int. Cl. H01J 37/32

(52) U.S. Cl. CPC H01J 37/32513; H01J 37/32449; H01J 37/32853

(57) ABSTRACT

In some examples, an isolation valve is provided to isolate gasses and plasmas in semiconductor manufacturing. An example isolation valve includes a valve body, a valve actuator, and a poppet. The poppet includes a gasket of a polytetrafluoroethylene (PTFE) material. The poppet is configured to move in the valve body by the valve actuator to (1) an engaged position where at least a portion of the gasket is contacting an opposing surface, or (2) a disengaged position where the gasket is not contacting the opposing surface.

### CLAIM OF PRIORITY

This application claims the benefit of priority to U.S. patent application Ser. No. 63/460,519, filed on Apr. 19, 2023, which is incorporated by reference herein in its entirety.

### TECHNICAL FIELD

The subject matter disclosed herein generally relates to an isolation valve for use in semiconductor manufacturing, and in some examples to components for an isolation valve such as an isolation valve gasket.

### BACKGROUND

Semiconductor substrate processing systems are used to process semiconductor substrates by techniques comprising etching, physical vapor deposition (PVD), atomic layer deposition (ALD), chemical vapor deposition (CVD), plasma-enhanced chemical vapor deposition (PECVD), pulsed deposition layer (PDL), plasma-enhanced pulsed deposition layer (PEPDL), and resist removal. One type of semiconductor substrate processing apparatus is a plasma processing apparatus that comprises a vacuum process chamber containing upper and lower electrodes. In a substrate processing cycle, a radio frequency (RF) power is applied between the electrodes to excite a process gas into plasma for processing semiconductor substrates in the chamber.

The vacuum process chamber is typically supplied by process gas supply lines. The process supply lines may include one or more isolation valves that operate to isolate process gasses from cleaning gasses, as needed.

Conventional isolation valves include O-ring sealing arrangements. High temperatures, aggressive dynamic response requirements, and hostile chemical environments can make valve applications particularly challenging in semiconductor processing. Isolation valves having conventional O-ring sealing arrangements fail quickly and often. Such O-ring failure is a limiting factor in extending the preventative maintenance (PM) cycle.

The background description provided herein is to generally present the context of the disclosure, It should be noted that the information described in this section is presented to provide the skilled artisan some context for the following disclosed subject matter and should not be considered as admitted prior art. More specifically, the work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods and systems are presented for isolating gasses, such as process and cleaning gasses in semiconductor manufacturing. Some examples include an isolation valve and components for an isolation valve (e.g., a poppet with an isolation valve gasket) for use in semiconductor manufacturing.

In some examples, an isolation valve includes a valve body, a valve actuator, and a poppet comprising a gasket of a polytetrafluoroethylene (PTFE) material. The poppet is configured to move in the valve body by the valve actuator to (1) an engaged position where at least a portion of the gasket is contacting an opposing surface, or (2) a disengaged position where the gasket is not contacting the opposing surface.

In some embodiments, the poppet includes a coupling channel, and wherein the gasket is secured to the poppet via the coupling channel.

In some embodiments, the coupling channel is configured in a plane of an upper surface of the poppet. In some aspects, the plane of the upper surface of the poppet is substantially parallel to a plane of the opposing surface.

In some embodiments, a lower surface of the gasket covers the upper surface of the poppet, and an upper surface of the gasket is configured to form a sealed contact with the opposing surface.

In some embodiments, the gasket includes at least one tab portion disposed along a circumference of a lower surface of the gasket. The at least one tab portion configured to fit within the coupling channel to secure the gasket to the poppet.

In some embodiments, the at least one tab portion comprises a first tab portion and a second tab portion. In some embodiments, the first tab portion and the second tab portion are configured opposite each other along the circumference of the lower surface of the gasket.

In some embodiments, each of the first tab portion and the second tab portion is configured with a length of approximately one-quarter of the circumference of the lower surface of the gasket.

In some embodiments, the at least one tab portion includes a first section of a first width, the first section protruding orthogonally to the lower surface of the gasket.

In some embodiments, the at least one tab portion comprises a second section of a second width, the second section protruding orthogonally to the first section, and the first width being smaller than the second width.

In some embodiments, the at least one tab portion is configured to form at least one gap between an outer surface of the at least one tab portion and an inner surface of the coupling channel.

In some embodiments, the poppet is configured to move in the valve body by the valve actuator without intervention of an O-ring.

In some embodiments, the poppet and the gasket comprise a unitary structure comprised entirely of, or constructed entirely from, the PTFE material.

In some embodiments, a gasket for an isolation valve includes a gasket of a polytetrafluoroethylene (PTFE) material. The gasket includes at least one tab portion disposed along a circumference of a lower surface of the gasket. The at least one tab portion is configured to fit within a coupling channel of a poppet of the isolation valve and secure the gasket to the poppet.

In some embodiments, the at least one tab portion comprises a first tab portion and a second tab portion. In some aspects, the first tab portion and the second tab portion are configured opposite each other along the circumference of the lower surface of the gasket.

In some embodiments, each of the first tab portion and the second tab portion is configured with a length of approximately one-quarter of the circumference of the lower surface of the gasket.

In some embodiments, each of the first tab portion and the second tab portion is configured with a length that is larger than approximately one-quarter of the circumference of the lower surface of the gasket.

In some embodiments, the at least one tab portion includes a first section of a first width, the first section protruding orthogonally to the lower surface of the gasket.

In some embodiments, the at least one tab portion comprises a second section of a second width. The second section protrudes orthogonally to the first section, and the first width being smaller than the second width.

In some embodiments, the at least one tab portion is configured to form at least one gap between an outer surface of the at least one tab portion and an inner surface of the coupling channel.

In some embodiments, a method of operating an isolation valve includes moving a poppet comprising a gasket of a polytetrafluoroethylene (PTFE) material to a disengaged position where the gasket is not contacting an opposing surface. Process gas is supplied to a process chamber via a gas supply line while the poppet is in the disengaged position. The poppet comprising the gasket of PTFE material is moved to an engaged position after a predetermined volume of the process gas is supplied to the process chamber, where at least a portion of the gasket is contacting the opposing surface in the engaged position.

In some embodiments, a cleaning gas or purging gas is supplied to the process chamber via the gas supply line. The poppet is moved between the disengaged position and the engaged position to control a volume of the cleaning gas or the purging gas entering the process chamber.

### BRIEF DESCRIPTION OF THE DRAWINGS

Various views of the appended drawings merely illustrate example embodiments of the present disclosure and should not be considered as limiting its scope.

FIG. 1 illustrates a process chamber, such as a deposition chamber, for manufacturing substrates, according to some example embodiments.

FIG. 2 is a schematic cross-section diagram of an isolation valve, according to an example embodiment.

FIG. 3 is an isometric view of a gasket used in the isolation valve of FIG. 2, according to example embodiments.

FIG. 4 and FIG. 5 are side pictorial views of example poppets including a gasket, according to example embodiments.

FIG. 6 and FIG. 7 are side pictorial views of example poppets including an O-ring of polytetrafluoroethylene (PTFE) material, according to example embodiments.

FIG. 8 is a block diagram illustrating an example of a machine upon which one or more example methods may be implemented, or by which one or more example embodiments may be controlled.

### DETAILED DESCRIPTION

Methods and systems are presented for isolating gasses, such as process and cleaning gasses and plasmas in semiconductor manufacturing. Example gasses and plasmas may include nitrogen trifluoride gas (NF3), hydrogen chloride gas (HCl), hydrogen fluoride gas (HF), fluorine-containing plasmas, and oxygen-containing plasmas. Some examples include an isolation valve and components for an isolation valve for use in semiconductor manufacturing. In the following description, for purposes of explanation, numerous specific details are set forth to provide a thorough understanding of example embodiments. It will be evident to one skilled in the art, however, that the present subject matter may be practiced without these specific details.

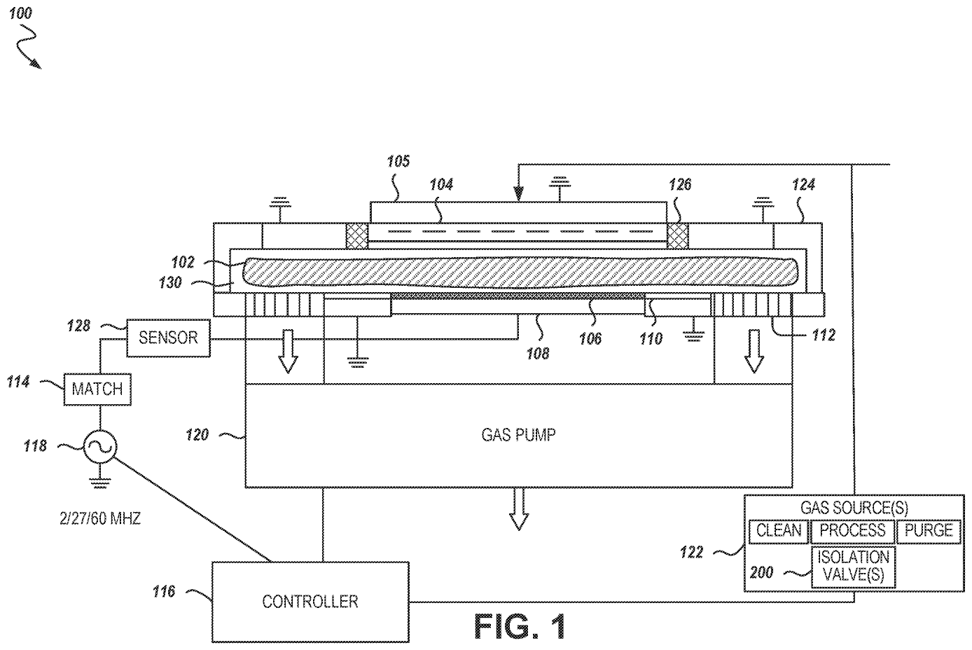

As used herein, the terms “wafer” and “substrate” are used interchangeably. A wafer or substrate indicates a support material upon which, or within which, elements of a semiconductor device are fabricated or attached. A substrate (e.g., substrate 106 in FIG. 1) may include, for example, wafers (e.g., having a diameter of 100 mm, 150 mm, 200 mm, 300 mm, 450 mm, or larger) composed of, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied). Example substrates include blanket substrates and patterned substrates. A blanket substrate is a substrate that comprises a low-surface (or planar) top surface. A patterned substrate is a substrate that comprises a high-surface (or structured) top surface. A structured top surface of a substrate may include different high-surface-area structures such as 3D NAND memory holes or other structures.

A general description of a process chamber using the disclosed apparatus and methods is provided with reference to FIG. 1. FIG. I illustrates a process chamber 100 (e.g., a semiconductor processing chamber for etching or deposition) for manufacturing substrates, according to one embodiment. In some examples, process chamber 100 may also be referred to as a vacuum chamber. Exciting an electric field between two electrodes is one of the methods to obtain radio frequency (RF) gas discharge in a process chamber. When an oscillating voltage is applied between the electrodes, the discharge obtained is referred to as a capacitively coupled plasma (CCP) discharge.

A plasma 102 may be created within a processing zone 130 of the process chamber 100, utilizing one or more process gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which may be pumped away. When a plasma is created, the positive ions are accelerated from the plasma across a space-charge sheath separating the plasma from chamber walls to strike the substrate surface with enough energy to remove material from the substrate surface. The process of using highly energetic and chemically reactive ions to selectively and anisotropically remove materials from a substrate surface is called Reactive Ion Etch (RIE). In some examples, process chamber 100 may be used in connection with PECVD or PEALD deposition processes.

A controller 116 manages the operation of process chamber 100, such as during processing, clean, and purge cycles, and by controlling the different elements in process chamber 100, such as RF generator 118, gas source(s) 122, and gas pump 120. The gas source(s) 122 may include a cleaning gas source, a process gas source, and a purge gas source. Other gas sources are possible. In one embodiment, fluorocarbon gases, such as CF4 and C4F8, are used in a dielectric etch process for their anisotropic and selective etching capabilities; but the principles described herein may be applied to other plasma-creating gases. The fluorocarbon gases are readily dissociated into chemically reactive by-products that include smaller molecular and atomic radicals. These chemically reactive by-products etch away the dielectric material.

Process chamber 100 illustrates a processing chamber with an upper (or top) electrode 104 and a lower (or bottom) electrode 108. An example process, in which an isolation valve of the present disclosure may be used, comprises a thermal ALD process which may, or may not, include an in-situ plasma. Other example processes may include techniques such as etching, physical vapor deposition (PVD), atomic layer deposition (ALD), chemical vapor deposition (CVD), plasma-enhanced chemical vapor deposition (PECVD), pulsed deposition layer (PDL), plasma-enhanced pulsed deposition layer (PEPDL), and resist removal. The upper electrode 104 may be grounded or coupled to an RF generator (not shown), and the lower electrode 108 is coupled to the RF generator 118 via a matching network 114. The RF generator 118 provides an RF signal between the upper electrode 104 and the lower electrode 108 to generate RF power in one or multiple (e.g., two or three) different RF frequencies. According to a desired configuration of the process chamber 100 for a particular operation, at least one of the multiple RF frequencies may be turned ON or OFF. In the embodiment shown in FIG. 1, the RF generator 118 is configured to provide at least three different frequencies, e.g., 400 kHz, 2 MHZ, 27 MHz, and 60 MHz, but other frequencies are also possible.

The process chamber 100 comprises a showerhead 105 on the upper electrode 104 to input process gas into the process chamber 100 provided by the gas source(s) 122, and a perforated confinement ring 112 that allows the gas to be pumped out of the process chamber 100 by gas pump 120. In some example embodiments, the gas pump 120 is a turbomolecular pump, but other types of gas pumps may be utilized.

When substrate 106 is present in process chamber 100, the silicon focus ring 110 can be situated next to substrate 106 such that there is a uniform RF field at the bottom surface of the plasma 102 for uniform etching (or deposition) on the surface of substrate 106. The embodiment of FIG. 1 shows a triode reactor configuration where the upper electrode 104 is surrounded by a ground electrode 124 (e.g., a symmetric RF ground electrode). Insulator 126 is a dielectric that isolates the ground electrode 124 from the upper electrode 104. Other implementations of process chamber 100, comprising ICP-based implementations, are also possible without changing the scope of the disclosed embodiments.

Each frequency generated by the RF generator 118 may be selected for a specific purpose in the substrate manufacturing process. In the example of FIG. 1, with RF powers provided at 400 kHz, 2 MHz, 27 MHz, and 60 MHz, the 400 kHz or 2 MHz RF power provides ion energy control, and the 27 MHz and 60 MHz powers provide control of the plasma density and the dissociation patterns of the chemistry. This configuration, where each RF power may be turned ON or OFF, enables certain processes that use ultra-low ion energy on the substrates, and certain processes (e.g., soft etch for low-k materials) where the ion energy has to be low (e.g., under 700 or 200 eV).

In another embodiment, a 60 MHz RF power is used on the upper electrode 104 to get ultra-low energies and very high density. This configuration allows chamber cleaning with high-density plasma when substrate 106 is not in the process chamber 100 while minimizing sputtering on the Electrostatic Chuck Surface (ESC). The ESC surface is exposed when substrate 106 is not present, and in this case, any ion energy on the surface should be avoided, which is why the bottom 2 MHz and 27 MHz power supplies may be off during cleaning.

In an example embodiment, process chamber 100 further comprises a sensor 128 which may be placed between the matching network 114 of the RF generator 118 and the lower electrode 108. The sensor 128 may include a voltage-current (or V-I) sensor configured to generate a plurality of signals (e.g., sensed data) that are indicative of at least one signal characteristic of RF signals generated by the RF generator 118 at a corresponding plurality of time instances. For example, the V-I sensor may generate a plurality of signals that are indicative of one or more of the following signal characteristics of RF signals: voltage, current, phase, delivered power, and impedance. In some examples, the plurality of signals generated by the sensor 128 at the corresponding plurality of time instances may be stored (e.g., in the on-chip memory of controller 116 or the sensor 128) and later retrieved (e.g., by the controller 116) for subsequent processing. In other aspects, the plurality of signals generated by the sensor 128, at the corresponding plurality of time instances, may be automatically communicated to the controller 116 as they are generated.

In some examples, the gas source(s) 122 are connected to one or more gas line supply arrangements disposed upstream of the gas showerhead on the upper electrode 104. The gas supply line arrangements may include one or more inlet manifolds (not visible in FIG. 1) connected to process chamber 100. The gas source(s) 122 may include one or more of a process gas source, a cleaning gas source, and a purge gas source, each controlled by one or more isolation valves 200. In some examples, the gas line supply arrangements are connected to these gas sources 122 and are used for cleaning and purge cycles of the process chamber 100 between or after substrate processing cycles. Other sources of gas and arrangements of isolation valves, gas manifolds, and gas control componentry are possible.

In some applications, a clean gas isolation valve 200 is used to isolate downstream process gases in a mixing gas injector block from upstream clean gas in a manifold. Application requirements may include an ability to operate at high temperatures (for example, 200° C.), a resistance to chlorine-containing deposition chemistry, a resistance to radical fluorine plasma/gas (such as a cleaning gas), an ability to operate dynamically (as opposed, for example, to a one-time use static seal), and allow for frequent use (for example, 1 to 2 times a day in a production environment). This combination of requirements, particularly the high-temperature ability, the dynamic nature, and chemical resistance can make the valve application particularly challenging. Conventional isolation valves use an O-ring seal that interfaces with an opposing sealing surface, for example, a process gas injector block. The O-ring seal moves in a linear motion to open and close the isolation valve and dynamically seal against the opposing surface. This traditional solution is ubiquitous in valve applications but frequently fails, sometimes only lasting one or two cycles of operation.

Current technology is susceptible to several failure mechanisms, such as temperature-induced O-ring deterioration. As O-ring polymer cross-links relax, filler materials can be released causing the mechanical properties of the O-ring to change unfavorably. Plasma-induced O-ring deterioration (both chemical and physical) can occur even in the best-performing O-rings designed for plasma applications and will be etched to 0.2-1% material loss at best, depending on conditions. In some instances, an isolation valve will be stuck closed. Here, the O-ring sticks between interfacing materials after exposure to temperature and chemistry, causing a separation force that is too high for the valve actuator to overcome. Moreover, when stuck, an isolation valve poppet (or closure) can break free from the valve actuator causing further damage to valve mounting features and the actuator. In other problems, the isolation valve body may overheat due to plasma recombination (exothermic) on the valve surfaces. In some instances, an isolation valve can heat up above a theoretical maximum operating temperature, causing degradation of the O-rings and other isolation valve components. O-ring material costs are high and high-purity sealing ceramic surfaces used in conventional isolation valves can be expensive. A. consequential problem caused by conventional O-ring degradation can include a lack of cleanliness and contamination downstream at a processed wafer. Chemical reactions, unwanted by-products, and material loss on the O-ring can enter process gas streams and cause defects on a processed wafer.

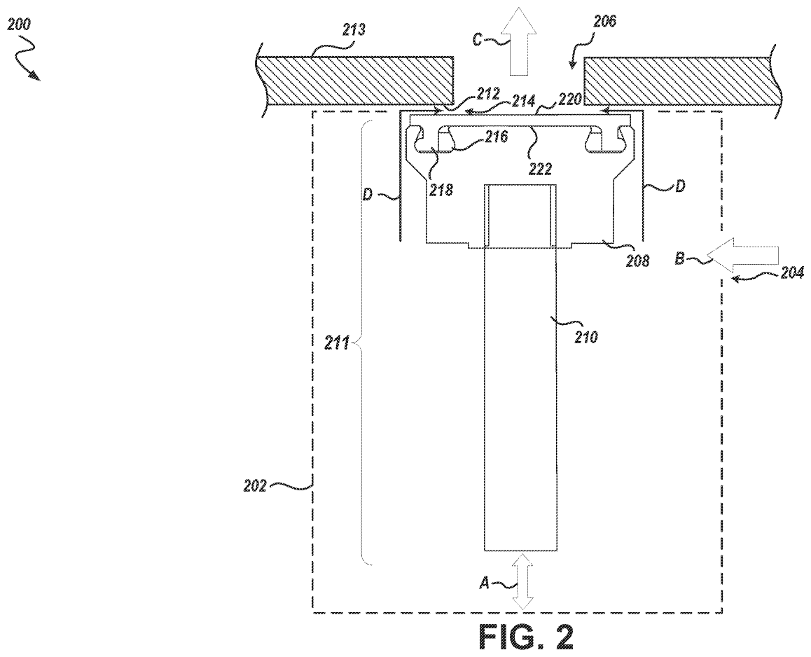

Present examples disclosed herein avoid the use of a polymer O-ring. Regarding FIG. 2, an isolation valve 200 comprises a valve body 202 shown schematically in a dashed outline. The body comprises an inlet shown generally at 204, and an outlet shown generally at 206. Other arrangements for an inlet and outlet are possible. The isolation valve 200 comprises a poppet 208 and a valve actuator 210. The valve actuator 210 and the poppet 208 together define a poppet valve assembly 211. The poppet valve assembly 211 can reciprocate axially (in the direction of arrow A) inside valve body 202 to open and close the inlet 204 and/or outlet 206 of the isolation valve 200. In some examples, the valve actuator 210 is responsible for moving the poppet valve assembly 211 as controlled by the controller 116 of FIG. 1. In some examples, the valve actuator 210 is configured to exert a spring force sufficient to seal the poppet 208 when held against an opposing surface 212 in a closed position of the isolation valve 200. In some examples, when the actuator (e.g., comprising a spring) is in a free state, the poppet 208 protrudes from the valve body 202 a short distance in the range of 1.0-1.5 mm which, when the spring is compressed, provides adequate clamping force to seal the poppet against the opposing surface 212 in use.

In some examples, the poppet valve assembly 211 is or comprises a unitary structure with the poppet 208 integrally formed with the valve actuator 210.

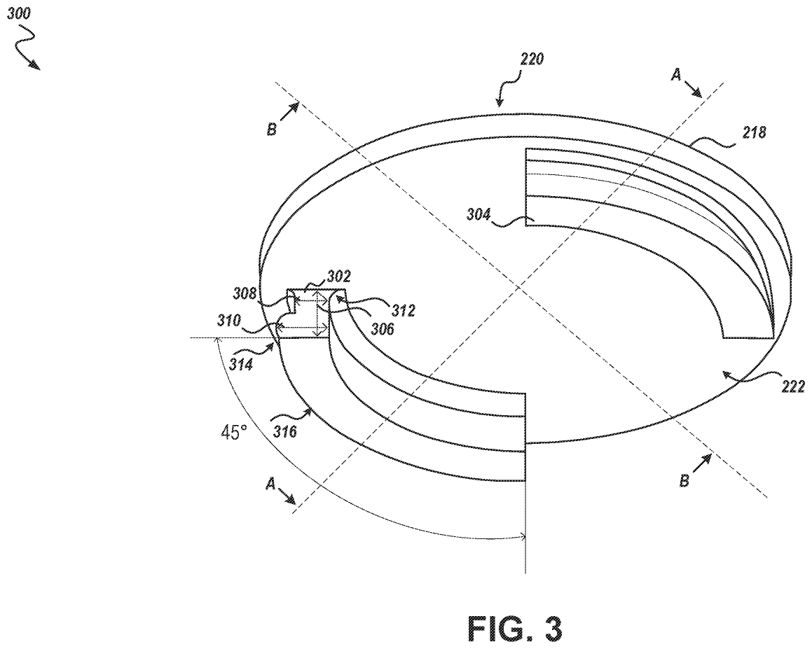

In some embodiments, the poppet 208 includes a gasket 218 seated in a coupling channel 216. The gasket can include an upper surface 220 and a lower surface 222. The upper surface 220 of gasket 218 can form a sealing engagement with the opposing surface 212 when the isolation valve 200 is closed. At least one tab portion (e.g., 302 and 304 in FIG. 3) can be mounted on the lower surface 222 and can be used for securing the gasket 218 to the poppet 208 via the coupling channel 216.

In some examples, to close the isolation valve 200, the poppet 208 can be moved so that the upper surface 220 of gasket 218 seals against an opposing surface 212 to block the passage of gas. The opposing surface 212 may be defined by an external component 213 to which the isolation valve 200 is fitted (for example, as shown), or provided inside valve body 202. Other arrangements are possible. The poppet 208 seals against the opposing surface 212 using the gasket 218, without an O-ring seal. When gasket 218 and poppet 208 are moved away from the opposing surface 212, isolation valve 200 is opened. When gasket 218 and the poppet 208 are moved in the other direction and gasket 218 engages with the opposing surface 212, the isolation valve 200 is closed.

When isolation valve 200 is open, gas can enter isolation valve 200 through inlet 204 as shown by arrow B, and exit valve 200 through outlet 206 as shown by arrow C. Example of the gas flow inside valve body 202 is shown by the arrows marked D. As shown, gas can pass through the inlet 204 and subsequently through a gap 214 between the poppet 208 and the opposing surface 212.

In some examples, gasket 218 comprises polytetrafluoroethylene (PTFE) material. In some examples, gasket 218 and/or poppet 208 is entirely constituted by or is formed from, a solid block of PTFE material. In some examples, only a portion or sub-section of the gasket 218 and/or the poppet 208 comprises PTFE material. In some examples, only a sealing surface (e.g., upper surface 220) of gasket 218, disposed opposite the opposing surface 212, is defined by or comprises PTFE material. Other configurations of portions or sub-sections of the gasket 218 and poppet 208 are possible. The PTFE material is used as a sealing material for the gasket 218 mounted on poppet 208 of isolation valve 200 and can engage fully with an opposing surface without the need for an O-ring to seal the inlet 204 and close valve 200. In some aspects, gasket 218 and/or poppet 208 are constituted by or is formed from, a compound that is based at least partially on PTFE material.

The use of a gasket 218 comprising PTFE as a sealing material can address many of the failure mechanisms discussed above. Primarily, the use of an O-ring and its attendant complications can be avoided. A gasket 218 comprising PTFE strongly resists temperature deterioration. The PTFE material does not include cross-links or filler materials and is generally safe for operation up to 260° C. Further, the PTFE material only comprises carbon-fluorine (C—F) bonds and is completely inert to radical fluorine and halide-containing chemistries such as HCl and chlorine trifluoride (CIF3) . In this regard, PTFE is compatible with NF3 and has an adequate operating temperature range (e.g., from about 55° C. to about 120° C. operating temperature range). Additionally, PTFE has been shown to provide sufficient seal required for isolation valve applications. In testing, some examples of a poppet 208 comprising a gasket with PTFE material were found to exhibit less than 0.01% by weight loss of PTFE material after long-term exposure (72 hours) to radical fluorine at 200 C. The conventional issue of stuck isolation valves is reduced, if not solved completely. PTFE has excellent low friction characteristics and requires near zero force to separate from an opposing surface when opening. The low friction reduces applied stresses and the consequent issue of valve poppet separation is addressed. Further, PTFE is thermally insulative and has a low (nearly zero) recombination rate with fluorine plasma. These characteristics help to reduce the issue of overheating valves. Wafer processing cleanliness is significantly improved as the PTFE material is very pure and, as it does not react with gasses and other plasma chemistry, there is very little, if any, material degradation to cause wafer contamination downstream of the isolation valve 200.

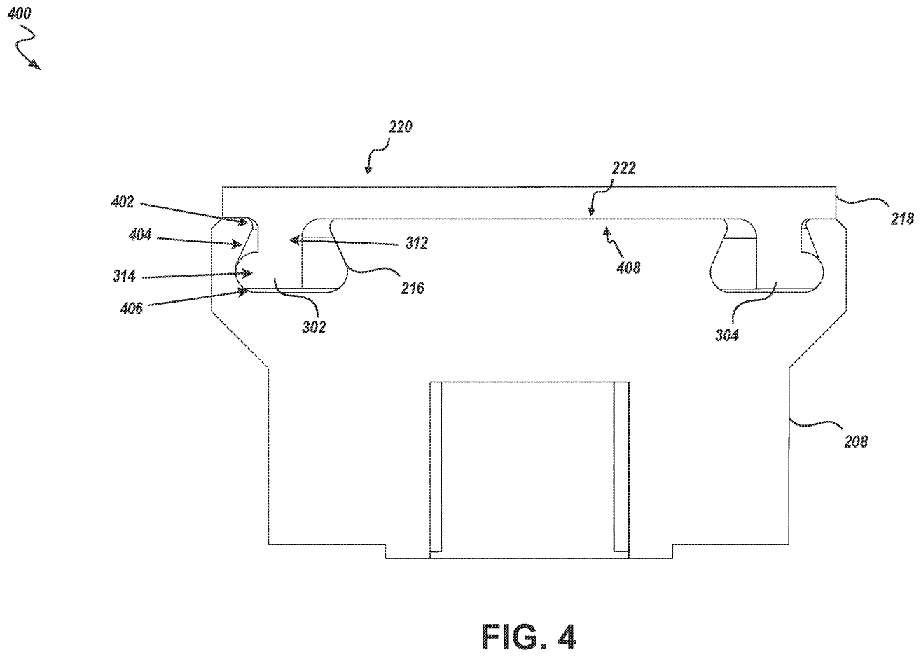

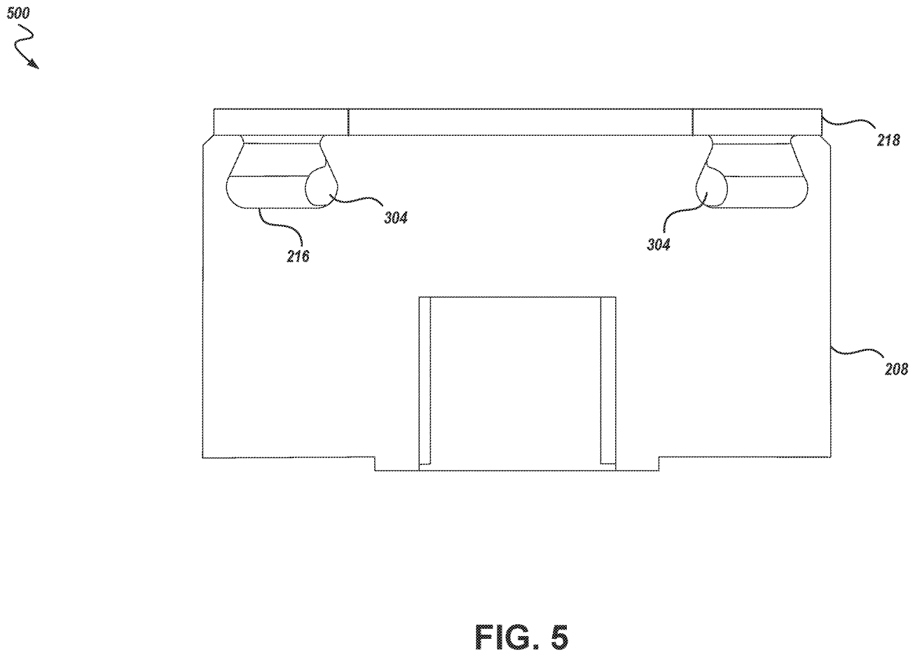

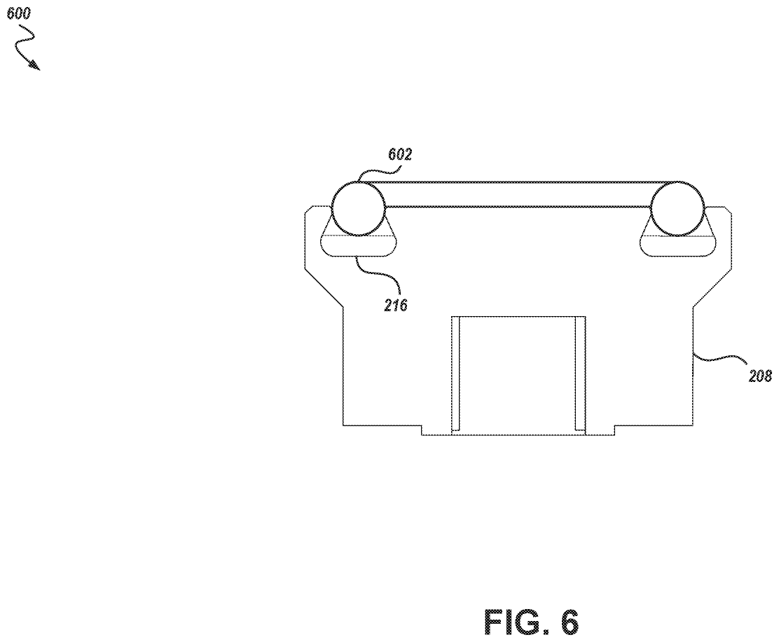

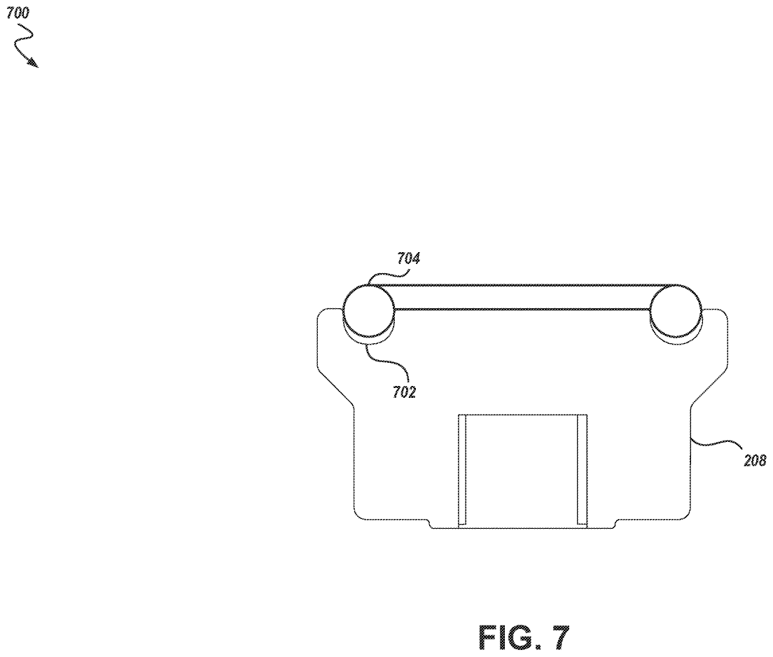

Isolation valves of the present disclosure including a poppet with a gasket made from PTFE material allow for using the benefits of PTFE without the need for a custom valve. More specifically, the gasket can include at least one tab portion to snap-fit into the coupling channel (e.g., a dovetail groove in the upper surface of the poppet used conventionally to accept an O-ring), ensuring the gasket attaches securely and does not fall out. The at least one tab portion also allows the gasket to be easily removed and replaced if required for maintenance. Additional features and configurations associated with the poppet 208 and the gasket 218 are discussed in connection with FIG. 3, FIG. 4, and FIG. 5. Examples of a poppet using a PTFE O-ring with different seating channels are illustrated in FIG. 6 and FIG. 7.

FIG. 3 is an isometric view 300 of gasket 218 used in the isolation valve of FIG. 2, according to example embodiments. Referring to FIG. 3, gasket 218 can be manufactured, at least partially, of PTFE material. In some aspects, gasket 218 includes one or more tab portions, such as a first tab portion 302 and a second tab portion 304. Tab portions 302 and 304 can be mounted on the lower surface 222 of gasket 218 and can be used to fit within the coupling channel 216 when attaching (or otherwise engaging) gasket 218 to poppet 208.

In some embodiments, each of the tab portions includes at least two sections associated with different dimensions and disposed orthogonally to each other. For example and as illustrated in FIG. 3, tab portion 302 includes a first section associated with width 308 and a second section 314 associated with width 310. In some aspects, the second section 314 protrudes orthogonally to the first section 312, resulting in a reverse-L profile (e.g., cross-sectional profile) of the tab portion 302, with the reverse-L profile associated with a height 306.

Even though FIG. 3 illustrates tab portions 302 and 304 as associated with a specific cross-sectional profile (e.g., reverse-L profile) with certain dimensions of the first and second sections, the disclosure is not limited in this regard and other cross-sectional profiles associated with different dimensions can be used for the one or more tab portions of the gasket 218. Considerations for selecting the cross-sectional profile and length of tab portions 302 and 304 includes profile and depth of coupling channel 216, ease of removal and placement of gasket 218 within the coupling channel 216 when attaching gasket 218 to poppet 208, etc. Even though the upper surface 220 of gasket 218 is illustrated as having circular shape, the disclosure is not limited in this regard and other shapes of the upper surface 220 (and in general of gasket 218) are possible based on a profile of the opposing surface 212 and/or shape or profile of outlet 206.

In some embodiments, tab portions 302 and 304 are disposed opposite each other. In some embodiments, each of the tab portions (e.g., tab portion 302) is configured with a length 316 of approximately one-quarter of the circumference of the lower surface of the gasket (e.g., as indicated in FIG. 3, the tab portion 302 spans a length corresponding to an angle of approximately 45°). In some examples, having the tab portions be approximately one-quarter (¼) of the circumference provides proper engagement with coupling channel while accounting for thermal expansion of the tabs in the coupling channel. Other lengths of the tab portions 302 and 304 of gasket 218 can be used as well. For example, tab portions 302 and 304 of gasket 218 can range from a length that is less than one-quarter of the circumference of the lower surface of the gasket to having a single tab portion encircling the entire circumference of the lower surface of the gasket.

Example side pictorial view 400 of poppet 208 is illustrated in FIG. 4, where the side pictorial view 400 is based on cross-cut A indicated in FIG. 3. Example side pictorial view 500 of poppet 208 is illustrated in FIG. 5, where the side pictorial view 500 is based on cross-cut B indicated in FIG. 3.

FIG. 4 and FIG. 5 are corresponding side pictorial views 400 and 500 of poppet 208 including gasket 218, according to example embodiments. Referring to FIG. 4, when gasket 218 is fully engaged to poppet 208 (e.g., the tab portions 302 and 304 of gasket 218 are snapped in the coupling channel 216), the lower surface 222 of gasket 218 substantially covers the upper surface 408 of poppet 208. In some embodiments, the dimensions of tab portions 302 and 304 (e.g., dimensions of the first section 312 and the second section 314 for each of the tabs) can be configured to obtain one or more gaps between a surface of the gasket 218 and a surface of the coupling channel 216. For example and as illustrated in FIG. 4, the dimensions of tab portions 302 and 304 are configured to obtain gaps 402, 404, and 406, which allow for thermal expansion of the gasket 218 (e.g., during a clean cycle) without diminishing the gasket's sealing capacity.

In some embodiments, the thickness of gasket 218 can be configured so that the bending stress generated during the gasket placement onto the poppet 208 does not exceed a threshold amount. In some aspects, the bending stress can be further adjusted by changing the length of each of the tab portions 302 and 304 (e.g., higher or lower than a circumference associated with a 45° angle).

FIG. 5 illustrates a side pictorial view 500 based on cross-cut B indicated in FIG. 3. More specifically, the side pictorial view 500 shows tab portion 304 when gasket 218 is fully engaged to poppet 208 (e.g., the tab portions 302 and 304 of gasket 218 are snapped in the coupling channel 216)

Even though FIGS. 3-5 illustrate the coupling channel 216 as having a dovetail profile, the disclosure is not limited in this regard and other types of seating channel profiles can be used as well (e.g., a half-circle profile as illustrated in FIG. 7).

In some examples, an isolation valve 200 includes a valve body 202, a valve actuator 210, and a poppet 208 comprising a gasket 218 of a polytetrafluoroethylene (PTFE) material. The poppet 208 is movable in the valve body 202 by the valve actuator 210 to hold the gasket 218 in a sealing engagement with an opposing surface 212 without the intervention of an O-ring.

In some examples, the poppet 208 comprises a coupling channel 216, and the gasket 218 is secured to the poppet 208 via the coupling channel.

In some examples, the coupling channel 216 is configured in a plane of a top (or upper) surface of the poppet (e.g., upper surface 408), and the plane of the upper surface 408 of the poppet is substantially parallel to the plane of the opposing surface 212.

In some examples, a lower surface of the gasket (e.g., lower surface 222) covers the upper surface 408 of the poppet, and the upper surface 220 of the gasket forms the sealing engagement with the opposing surface.

In some examples, gasket 218 comprises at least one tab portion (e.g., tab portions 302 and 304) disposed along a circumference of a lower surface of the gasket. The at least one tab portion is configured to fit within the coupling channel to engage the gasket to the poppet.

In some examples, the at least one tab portion comprises a first tab portion 302 and a second tab portion 304. The first tab portion and the second tab portion are configured opposite each other along the circumference of the lower surface of gasket 218.

In some examples, each of the first tab portion 302 and the second tab portion 304 is configured with a length of approximately one-quarter of the circumference of the lower surface of the gasket 218.

In some examples, the at least one tab portion comprises a first section 312 of a first width 308, the first section protruding orthogonally to the lower surface of the gasket.

In some examples, the at least one tab portion comprises a second section 314 of a second width 310, the second section protruding orthogonally to the first section, and the first width 308 being smaller than the second width 310.

In some examples, the at least one tab portion (e.g., the first tab portion 302 and/or second tab portion 304) is configured to form at least one gap (e.g., one or more of gaps 402-406) between an outer surface of the at least one tab portion and an inner surface of the coupling channel.

In some examples, the poppet 208 and the gasket 218 comprise a unitary structure comprised entirely of or constructed entirely from the PTFE material.

In some examples, the poppet 208 and the gasket 218 comprise a unitary structure comprised partially of, or constructed partially from the PTFE material.

In some examples, two or more of the valve actuator 210, the poppet 208, and the gasket 218 can be configured as a unitary structure comprised partially of, or constructed partially from the PTFE material.

FIG. 6 and FIG. 7 are side pictorial views of example poppets including an O-ring of polytetrafluoroethylene (PTFE) material, according to example embodiments. Referring to FIG. 6, side pictorial view 600 illustrates poppet 208 including a dovetail-shaped coupling channel 216 configured to receive O-ring 602 constructed of PTFE material. Referring to FIG. 7, side pictorial view 700 illustrates poppet 208 including a semi-circular-shaped coupling channel 702 configured to receive O-ring 704 constructed of PTFE material.

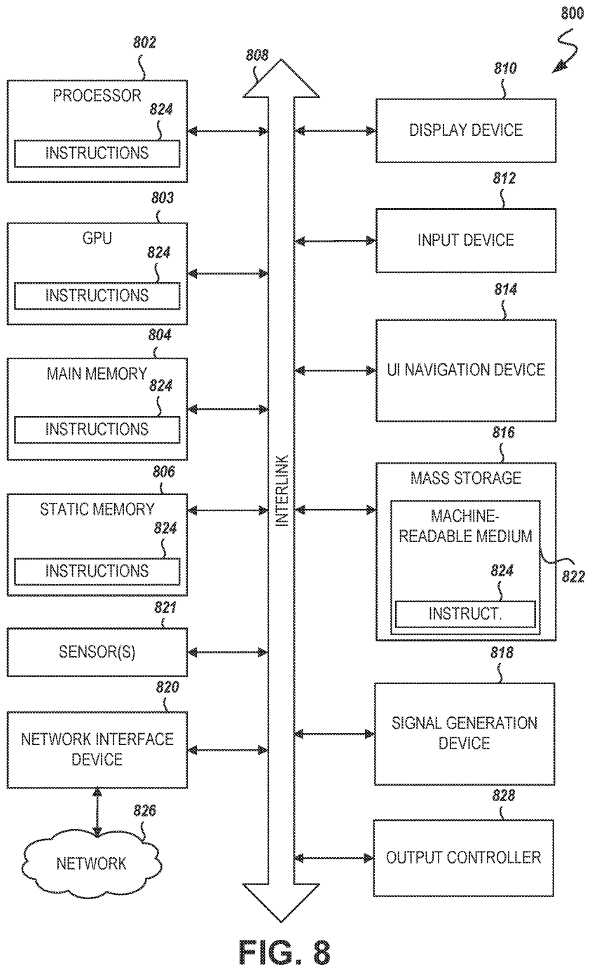

FIG. 8 is a block diagram illustrating an example of a machine 800 (such as the controller 116 of FIG. 1) upon or by which one or more example process embodiments described herein may be implemented or controlled. In alternative embodiments, the machine 800 may operate as a standalone device or may be connected (e.g., networked) to other machines. In a networked deployment, machine 800 may operate in the capacity of a server machine, a client machine, or both in server-client network environments. In an example, machine 800 may act as a peer machine in a peer-to-peer (P2P) (or other distributed) network environment. Further, while only a single machine 800 is illustrated, the term “machine” shall also be taken to include any collection of machines that individually or jointly execute a set (or multiple sets) of instructions to perform any one or more of the methodologies discussed herein, such as via cloud computing, software as a service (Saas), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when in use. In one example, the hardware of the circuitry may be immutably designed to carry out a specific operation (e.g., hardwired). In another example, the hardware of the circuitry may include variably connected physical components, (e.g., execution units, transistors, simple circuits) comprising a computer-readable medium physically modified (e.g., magnetically and electrically by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some examples, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 800 may include a hardware processor 802 (e.g., a central processing unit (CPU), a hardware processor core, or any combination thereof), a graphics processing unit (GPU) 803, a main memory 804, and a static memory 806; some or all of which may communicate with each other via an interlink (e.g., bus) 808. The machine 800 may further include a display device 810, an alphanumeric input device 812 (e.g., a keyboard), and a user interface (UI) navigation device 814 (e.g., a mouse). In an example, the display device 810, alphanumeric input device 812, and UI navigation device 814 may be a touch screen display. The machine 800 may additionally include a mass storage device (e.g., drive unit) 816, a signal generation device 818 (e.g., a speaker), a network interface device 820, and one or more sensors 821, such as a Global Positioning System (GPS) sensor, compass, accelerometer, or another sensor. The machine 800 may include an output controller 828, such as a serial (e.g., Universal Serial Bus (USB)), parallel, or other wired or wireless (e.g., Infrared (IR), Near Field Communication (NFC)) connection to communicate with or control one or more peripheral devices (e.g., a printer, card reader).

In an example embodiment, the hardware processor 802 may perform the functionalities of the controller 116 discussed herein.

The mass storage device 816 may include a machine-readable medium 822 on which is stored one or more sets of data structures or instructions 824 (e.g., software) embodying or utilized by any one or more of the techniques or functions described herein. The instructions 824 may also reside, completely or at least partially, within the main memory 804, within the static memory 806, within the hardware processor 802, or the GPU 803 during execution thereof by the machine 800. In an example, one or any combination of the hardware processor 802, the GPU 803, the main memory 804, the static memory 806, or the mass storage device 816 may constitute machine-readable media.

While the machine-readable medium 822 is illustrated as a single medium, the term “machine-readable medium” may include a single medium or multiple media, (e.g., a centralized or distributed database, and/or associated caches and servers) configured to store the one or more instructions 824.

The term “machine-readable medium” may include any medium that is capable of storing, encoding, or carrying instructions 824 for execution by machine 800 and that causes the machine 800 to perform any one or more of the techniques of the present disclosure, or that is capable of storing, encoding, or carrying data structures used by or associated with such instructions 824. Non-limiting machine-readable medium examples may include solid-state memories and optical and magnetic media. In an example, a massed machine-readable medium comprises a machine-readable medium 822 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 824 may further be transmitted or received over a communications network 826 using a transmission medium via the network interface device 820.

Implementation of the preceding techniques may be accomplished through any number of specifications, configurations, or example deployments of hardware and software. It should be understood that the functional units or capabilities described in this specification may have been referred to or labeled as components or modules to emphasize their implementation independence more particularly. Such components may be embodied by any number of software or hardware forms. For example, a component or module may be implemented as a hardware circuit comprising custom, very-large-scale integration (VLSI) circuits, gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center) than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations comprising different storage devices, and may exist, at least partially, merely as electronic signals on a system or network. The components or modules may be passive or active, comprising agents operable to perform desired functions.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated berein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used berein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in the context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

1. An isolation valve comprising:
a valve body;
a valve actuator; and
a poppet comprising a gasket of a polytetrafluoroethylene (PTFE) material, the poppet is configured to move in the valve body by the valve actuator to (1) an engaged position where at least a portion of the gasket is contacting an opposing surface, or (2) a disengaged position where the gasket is not contacting the opposing surface.

2. The isolation valve of claim 1, wherein the poppet comprises a coupling channel, and wherein the gasket is secured to the poppet via the coupling channel.

3. The isolation valve of claim 2, wherein the coupling channel is configured in a plane of an upper surface of the poppet, and wherein the plane of the upper surface of the poppet is substantially parallel to a plane of the opposing surface.

4. The isolation valve of claim 3, wherein a lower surface of the gasket covers the upper surface of the poppet, and an upper surface of the gasket is configured to form a sealed contact with the opposing surface.

5. The isolation valve of claim 2, wherein the gasket comprises at least one tab portion disposed along a circumference of a lower surface of the gasket, the at least one tab portion configured to fit within the coupling channel to secure the gasket to the poppet.

6. The isolation valve of claim 5, wherein the at least one tab portion comprises a first tab portion and a second tab portion, and wherein the first tab portion and the second tab portion are configured opposite each other along the circumference of the lower surface of the gasket.

7. The isolation valve of claim 6, wherein each of the first tab portion and the second tab portion is configured with a length of approximately one-quarter of the circumference of the lower surface of the gasket.

8. The isolation valve of claim 5, wherein the at least one tab portion comprises a first section of a first width, the first section protruding orthogonally to the lower surface of the gasket.

9. The isolation valve of claim 8, wherein the at least one tab portion comprises a second section of a second width, the second section protruding orthogonally to the first section, and the first width being smaller than the second width.

10. The isolation valve of claim 5, wherein the at least one tab portion is configured to form at least one gap between an outer surface of the at least one tab portion and an inner surface of the coupling channel.

11. The isolation valve of claim 1, wherein the poppet is configured to move in the valve body by the valve actuator without intervention of an O-ring.

12. The isolation valve of claim 1, wherein the poppet and the gasket comprise a unitary structure comprised entirely of, or constructed entirely from, the PTFE material.

13. A gasket for an isolation valve, the gasket comprising:
a gasket of a polytetrafluoroethylene (PTFE) material, the gasket comprising:
at least one tab portion disposed along a circumference of a lower surface of the gasket, the at least one tab portion configured to fit within a coupling channel of a poppet of the isolation valve and secure the gasket to the poppet.

14. The gasket of claim 13, wherein the at least one tab portion comprises a first tab portion and a second tab portion, and wherein the first tab portion and the second tab portion are configured opposite each other along the circumference of the lower surface of the gasket.

15. The gasket of claim 14, wherein each of the first tab portion and the second tab portion is configured with a length of approximately one-quarter of the circumference of the lower surface of the gasket.

16. The gasket of claim 14, wherein each of the first tab portion and the second tab portion is configured with a length that is larger than approximately one-quarter of the circumference of the lower surface of the gasket.

17. The gasket of claim 13, wherein the at least one tab portion comprises a first section of a first width, the first section protruding orthogonally to the lower surface of the gasket.

18. The gasket of claim 17, wherein the at least one tab portion comprises a second section of a second width, the second section protruding orthogonally to the first section, and the first width being smaller than the second width.

19. The gasket of claim 13, wherein the at least one tab portion is configured to form at least one gap between an outer surface of the at least one tab portion and an inner surface of the coupling channel.

20. A method of operating an isolation valve, the method comprising:
moving a poppet comprising a gasket of a polytetrafluoroethylene (PTFE) material to a disengaged position where the gasket is not contacting an opposing surface;
supplying process gas to a process chamber via a gas supply line while the poppet is in the disengaged position; and
moving the poppet comprising the gasket of PTFE material to an engaged position after a predetermined volume of the process gas is supplied to the process chamber, wherein at least a portion of the gasket is contacting the opposing surface in the engaged position.

21. The method of claim 20, further comprising:
supplying a cleaning gas or purging gas to the process chamber via the gas supply line; and
moving the poppet between the disengaged position and the engaged position to control a volume of the cleaning gas or the purging gas entering the process chamber.
